(19) United States
(12) Patent Application Publication
(10) Pub. No.: US 2025/0372436 A1
(43) Pub. Date: Dec. 4, 2025

(54) SEMICONDUCTOR MANUFACTURING APPARATUS AND METHOD FOR MANUFACTURING SEMICONDUCTOR APPARATUS

(71) Applicant: Mitsubishi Electric Corporation, Tokyo (JP)

(72) Inventors: Takuyo NAKAMURA, Tokyo (JP); Shigehisa YAMAMOTO, Tokyo (JP)

(73) Assignee: Mitsubishi Electric Corporation, Tokyo (JP)

(21) Appl. No.: 19/011,356

(22) Filed: Jan. 6, 2025

(30) Foreign Application Priority Data
May 30, 2024 (JP) 2024-088087

(51) Int. Cl. H01L 21/687; C23C 16/458; C30B 25/12

(52) U.S. Cl. CPC H01L 21/68735; C23C 16/4585; C23C 16/4586; C30B 25/12

(57) ABSTRACT

According to the present disclosure, a semiconductor manufacturing apparatus comprises a susceptor and a gas inlet located above the susceptor. The susceptor includes a holder portion on which a substrate is to be placed, and a foreign material collection region provided to enclose a peripheral region of the holder portion. The foreign material collection region includes an opening portion, an opening of which is located at the same level as an uppermost portion of the holder portion, and a collection portion located at a lower level than the opening portion. An opening width of the opening portion is narrower than an opening width of the collection portion. Gas introduced from the gas inlet flows toward an outer periphery from a center of the substrate on an upper surface of the substrate and flows into the opening portion.

### BACKGROUND OF THE INVENTION

### FIELD

The present disclosure relates to a semiconductor manufacturing apparatus and a method for manufacturing semiconductor apparatus.

### BACKGROUND

In a film formation apparatus, a film is sometimes formed on an upper surface of a susceptor as well as on an upper surface of a substrate. Due to the film formed on the upper surface of the susceptor, a problem arises that the substrate adheres to the susceptor. To solve this problem, JP 2022-121078 A discloses a technique of configuring a susceptor having a double structure.

However, with the above-described method, film formation itself in a peripheral portion on an upper surface of a susceptor cannot be prevented. There is a problem that this film floats around a substrate during subsequent film formation processing and finally adheres to an upper surface of the substrate.

### SUMMARY

In view of the above-described problems, an object of the present disclosure is to provide a semiconductor manufacturing apparatus or a method for manufacturing a semiconductor apparatus capable of preventing a film formed in a peripheral portion on an upper surface of a susceptor from adhering to an upper surface of a substrate as a result of the foreign material collection region being provided, by providing a foreign substance collection region having an opening portion and a collection portion in a susceptor.

The features and advantages of the present disclosure may be summarized as follows.

A semiconductor manufacturing apparatus according to the present disclosure includes: a susceptor; and a gas inlet located above the susceptor, wherein the susceptor includes a holder portion on which a substrate is to be placed, and a foreign material collection region provided to enclose a peripheral region of the holder portion, the foreign material collection region includes an opening portion, an opening of which is located at the same level as an uppermost portion of the holder portion, and a collection portion located at a lower level than the opening portion, an opening width of the opening portion is narrower than an opening width of the collection portion, and gas introduced from the gas inlet flows toward an outer periphery from a center of the substrate on an upper surface of the substrate and flows into the opening portion.

Other and further objects, features and advantages of the disclosure will appear more fully from the following description.

### BRIEF DESCRIPTION OF DRAWINGS

FIG. 1 is a cross-sectional view illustrating a semiconductor manufacturing apparatus according to a first embodiment of the present disclosure.

FIG. 2 is a flowchart indicating a process of manufacturing the SiC wafer according to the first embodiment of the present disclosure.

FIG. 3 is a cross-sectional view illustrating a semiconductor manufacturing apparatus according to a first modification of the first embodiment of the present disclosure.

FIG. 4 is a cross-sectional view illustrating a semiconductor manufacturing apparatus according to a second modification of the first embodiment of the present disclosure.

FIG. 5 is a view illustrating a semiconductor manufacturing apparatus according to a second embodiment of the present disclosure.

FIG. 6 is a view illustrating the inverse tapered portion according to the second embodiment of the present disclosure.

FIG. 7 is a view illustrating a semiconductor manufacturing apparatus according to a third embodiment of the present disclosure.

FIG. 8 is a top view illustrating a first modification of the susceptor according to the third embodiment of the present disclosure.

FIG. 9 is a top view illustrating a second modification of the susceptor according to the third embodiment of the present disclosure.

FIG. 10 is a top view illustrating a third modification of the susceptor according to the third embodiment of the present disclosure.

FIG. 11 is a top view illustrating a fourth modification of the susceptor according to the third embodiment of the present disclosure.

FIG. 12 is a view illustrating a semiconductor manufacturing apparatus according to a fourth embodiment of the present disclosure.

### DESCRIPTION OF EMBODIMENTS

### First Embodiment

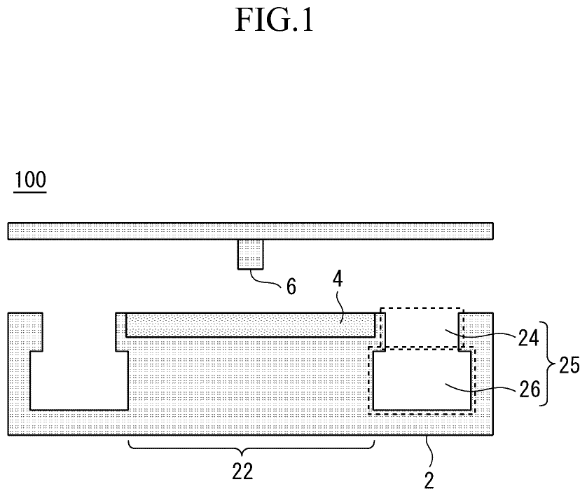

FIG. 1 is a cross-sectional view illustrating a semiconductor manufacturing apparatus according to a first embodiment of the present disclosure. A semiconductor manufacturing apparatus 100 is a substrate processing apparatus. In the present embodiment, for example, an aspect will be described where the semiconductor manufacturing apparatus 100 manufactures an SiC wafer to manufacture a power device.

The semiconductor manufacturing apparatus 100 includes a susceptor 2. The susceptor 2 includes a holder portion 22 on which a substrate 4 is to be placed. Here, the substrate 4 is an n-type SiC substrate. Further, the holder portion 22 is provided with a counterbore. The counterbore prevents the substrate 4 from being displaced during growth of an epitaxial layer which will be described later by the substrate 4 being placed inside the counterbore. The counterbore may have, for example, a thickness equivalent to a thickness of the substrate 4.

Note that in a case where the substrate 4 is a substrate having a diameter of equal to or greater than 6 inches, there is a case where warpage of the substrate 4 becomes great during the growth of the epitaxial layer which will be described later. Thus, a bottom surface of the counterbore portion described above may have a bowl shape. This shape can prevent a central portion of the substrate 4 from coming into contact with the bottom surface of the counterbore portion during the growth of the epitaxial layer, so that it is possible to prevent temperature decrease at the central portion of the substrate 4. This results in improving in-plane uniformity of a film thickness and carrier concentration of the epitaxial layer.

Further, the susceptor 2 has a foreign material collection region 25 provided so as to enclose a peripheral region of the holder portion 22. The foreign material collection region 25 includes an opening portion 24, an opening of which is located at the same level as an uppermost portion of the holder portion 22, and a collection portion 26 located at a lower level than the opening portion 24. The opening portion 24 has an opening width narrower than an opening width of the collection portion 26 and encloses the peripheral region of the holder portion 22. In other words, in a cross-sectional view, an area of the opening portion 24 is smaller than an area of the collection portion 26.

The opening width of the opening portion 24 may be determined in accordance with a film thickness of a foreign material to be deposited by the semiconductor manufacturing apparatus 100 from start of film formation until internal reset. It is, for example, assumed that a total cumulative film thickness of the epitaxial layer made to grow by the semiconductor manufacturing apparatus 100 from start of film formation until internal reset is 200 μm. In this case, a film thickness of the foreign material locally depositing in an outer end portion of the holder portion 22 is approximately 100 μm. Thus, the opening width of the opening portion 24 is preferably set at 200 to 300 μm that is a value greater than the film thickness of the foreign material.

Note that the above-described total cumulative film thickness may be set at a film thickness sufficient to make quality of an SiC wafer to be manufactured equal to or higher than a specific level. The specific level may be determined so that, for example, in-plane uniformity of the film thickness and carrier concentration of the epitaxial layer growing by a thermal CVD method is higher than a specific level, and the number of crystal faults that have occurred is lower than a specific level.

Further, the foreign material collection region 25 is formed by removing part of the susceptor 2. In other words, the susceptor 2 is an integrated type unlike with a susceptor 2a which will be described later. As a result, in the susceptor 2, work for attaching a ring cover that is required in the susceptor 2a which will be described later is not required, so that productivity can be improved.

Further, the semiconductor manufacturing apparatus 100 includes a gas inlet 6 located above the susceptor 2. The introduced gas flows toward an outer periphery from the center of the substrate 4 on an upper surface of the substrate 4 placed on the holder portion 22 and flows into the opening portion 24. In accordance with the flow of this gas, a foreign material flows into the opening portion 24.

Further, the collection portion 26 is located at a lower level than the substrate 4 placed on the holder portion 22. Thus, the foreign material flowing into the opening portion 24 flows into the collection portion 26 by gravity.

Note that the gas to be introduced from the gas inlet 6 is, for example, source gas and carrier gas such as hydrogen gas. The source gas is a raw material to be used for growth of a single crystal thin film, and is, for example, silicon source gas and carbon source gas. The silicon source gas is, for example, silane gas or chlorosilane gas. The carbon source gas is, for example, propane or methane.

An effect obtained by the foreign material collection region 25 being provided in the susceptor 2 will be described. During growth of the epitaxial layer, the epitaxial layer is formed on the whole upper surface of the susceptor 2. As a result, the epitaxial layer is formed not only on the upper surface of the substrate 4 but also in a peripheral portion on the upper surface of the susceptor 2. The epitaxial layer formed in the peripheral portion on the upper surface of the susceptor 2 is not necessary in a step of manufacturing an SiC wafer, and thus, will be hereinafter referred to as a foreign material.

The foreign material formed in the peripheral portion on the upper surface of the susceptor 2 may be exfoliated from the susceptor 2 during subsequent growth of the epitaxial layer. There is a possibility that the exfoliated foreign material may float around the substrate 4 and finally adhere to the upper surface of the substrate 4. If the foreign material adheres to the upper surface of the substrate 4, a problem such as decrease in in-plane uniformity of a film thickness of the epitaxial layer to be formed on the substrate 4 occurs. It is therefore necessary to prevent the foreign material from adhering to the upper surface of the substrate 4.

In the present embodiment, the susceptor 2 is provided with the foreign material collection region 25. Thus, the above-described exfoliated foreign material flows into the foreign material collection region 25 in accordance with flow of the gas and gravity. This results in making it possible to prevent the foreign material from adhering to the upper surface of the substrate 4.

Further, in the present embodiment, by the susceptor 2 being provided with the foreign material collection region 25, an area of a region corresponding to the peripheral portion on the upper surface of the susceptor 2 is reduced. This results in making it possible to reduce a total amount of the epitaxial layer to be formed in the peripheral portion on the upper surface of the susceptor 2.

Further, as described above, in the present embodiment, a foreign material that has been formed in the peripheral portion on the upper surface of the susceptor 2 in related art deposits on a bottom surface of the collection portion 26. Here, a case will be considered where the foreign material floats from the bottom surface of the collection portion 26 during the subsequent growth of the epitaxial layer. The collection portion 26 is located at a lower level than the upper surface of the susceptor 2. Further, the opening width of the opening portion 24 is narrower than the opening width of the collection portion 26. Thus, it is difficult for the foreign material floating during the subsequent growth of the epitaxial layer to reach the circumference of the substrate 4. In other words, it is possible to prevent the foreign material from floating and adhering again to the upper surface of the substrate 4.

As described above, the susceptor 2 according to the present embodiment is provided with the foreign material collection region 25. This results in making it possible to prevent the film formed in the peripheral portion on the upper surface of the susceptor 2 from adhering to the upper surface of the substrate 4.

Further, according to the present embodiment, it is possible to inhibit the foreign material from adhering inside of the semiconductor manufacturing apparatus 100. This results in making it possible to simplify apparatus maintenance to be performed for internal reset of the semiconductor manufacturing apparatus 100. Further, according to the present embodiment, the film formed in the peripheral portion on the upper surface of the susceptor 2 can be prevented from adhering to the upper surface of the substrate 4, so that it is possible to improve productivity of an SiC wafer.

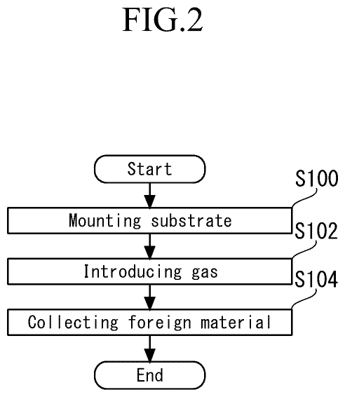

FIG. 2 is a flowchart indicating a process of manufacturing the SiC wafer according to the first embodiment of the present disclosure. First, in step 100, the substrate 4 is mounted on the susceptor 2. As described above, the substrate 4 is mounted on the holder portion 22 of the susceptor 2.

Then, in step 102, gas is introduced from the gas inlet 6. As described above, the gas introduced from the gas inlet 6 is, for example, source gas and carrier gas such as hydrogen gas. The SiC wafer is manufactured by the gas introduced in the present step.

A specific method of manufacturing the SiC wafer will be described. Here, an example will be described where the SiC wafer is manufactured using a thermal chemical vapor deposition method. Hereinafter, this thermal chemical vapor deposition method will be referred to as a thermal CVD method.

First, the substrate 4 is placed on the holder portion 22. Subsequently, the susceptor 2 is rotated, and at the same time, the gas is introduced from the gas inlet 6. Here, a temperature condition, and the like, inside the semiconductor manufacturing apparatus 100 are optimized. As a result, an n-type SiC epitaxial layer having lower impurity concentration than the substrate 4 is formed on the substrate 4 that is an n-type SiC substrate by the thermal CVD method. Hereinafter, this layer will be simply referred to as an epitaxial layer.

The grown epitaxial layer blocks a basal plane dislocation (BPD) on the SiC wafer. Thus, in the SiC wafer obtained by making the epitaxial layer grow, doping concentration of impurities can be easily controlled.

Then, in step 104, the above-described foreign material is collected in the foreign material collection region 25, and the process of manufacturing the SiC wafer is completed. As described above, the foreign material is collected in the foreign material collection region 25 by the gas introduced from the gas inlet 6 flowing toward the outer periphery from the center of the substrate 4 on the upper surface of the substrate 4.

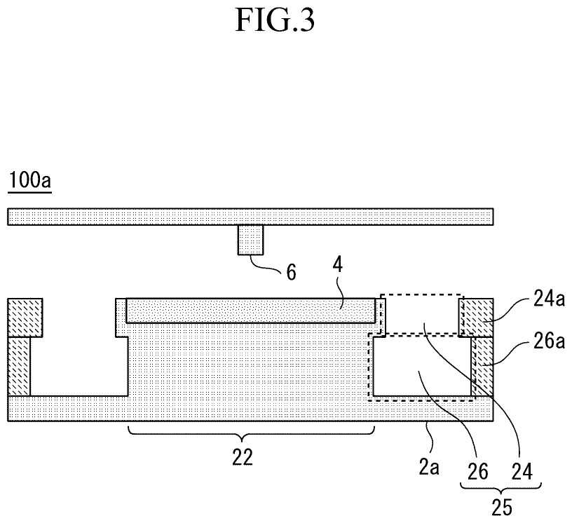

Subsequently, modifications of the present embodiment will be described. FIG. 3 is a cross-sectional view illustrating a semiconductor manufacturing apparatus according to a first modification of the first embodiment of the present disclosure. A semiconductor manufacturing apparatus 100a is different from the semiconductor manufacturing apparatus 100 in that an upper ring cover 24a and a lower ring cover 26a are provided.

The semiconductor manufacturing apparatus 100a includes a susceptor 2a. The susceptor 2a includes the holder portion 22 on which the substrate 4 is to be placed. Further, the susceptor 2a has the foreign material collection region 25 provided to enclose a peripheral region of the holder portion 22. The foreign material collection region 25 includes the opening portion 24 and the collection portion 26.

The lower ring cover 26a is installed on the susceptor 2a. The upper ring cover 24a is installed on the lower ring cover 26a. The lower ring cover 26a and the upper ring cover 24a are ring-shaped covers provided on the outer periphery of the holder portion 22.

In the present modification, the opening portion 24 is a region enclosed by the holder portion 22 and the upper ring cover 24a, and the collection portion 26 is a region enclosed by the holder portion 22 and the lower ring cover 26a. Thus, in the semiconductor manufacturing apparatus 100a, the opening widths of the opening portion 24 and the collection portion 26 can be optionally changed by changing design of the upper ring cover 24a and the lower ring cover 26a in accordance with a size or an amount of the foreign material desired to be collected.

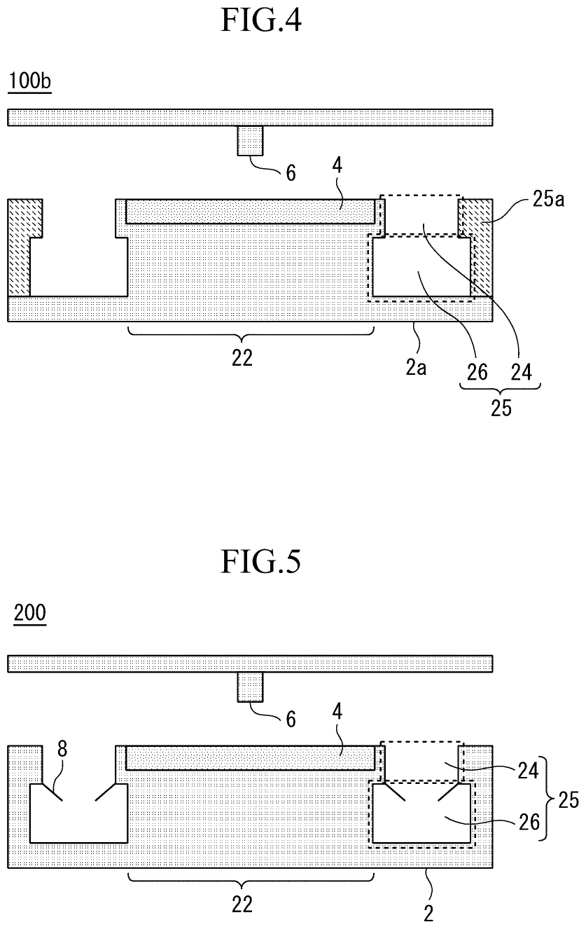

FIG. 4 is a cross-sectional view illustrating a semiconductor manufacturing apparatus according to a second modification of the first embodiment of the present disclosure. A semiconductor manufacturing apparatus 100b is different from the semiconductor manufacturing apparatus 100 in that a ring cover 25a is provided.

The semiconductor manufacturing apparatus 100b includes the susceptor 2a. The ring cover 25a is installed on the susceptor 2a. The ring cover 25a is a ring-shaped cover provided on the outer periphery of the holder portion 22. Further, an inner diameter of the ring cover 25a on the upper surface side is smaller than an inner diameter on the bottom surface side.

In the present modification, the opening portion 24 is a region enclosed by the holder portion 22 and the ring cover 25a, and the collection portion 26 is a region enclosed by the holder portion 22 and the ring cover 25a. Thus, in the semiconductor manufacturing apparatus 100b, the opening widths of the opening portion 24 and the collection portion 26 can be optionally changed by changing design of the ring cover 25a in accordance with a size or an amount of the foreign matter desired to be collected.

### Second Embodiment

FIG. 5 is a view illustrating a semiconductor manufacturing apparatus according to a second embodiment of the present disclosure. A semiconductor manufacturing apparatus 200 is different from the semiconductor manufacturing apparatus 100 in that an inverse tapered portion 8 is provided inside the foreign material collection region 25.

The foreign material collection region 25 includes the inverse tapered portion 8 provided between the opening portion 24 and the collection portion 26. The foreign material that has deposited in the collection portion 26 collides with the inverse tapered portion 8 in a case where the foreign material floats. This results in making it further difficult for the foreign material to reach the circumference of the substrate 4.

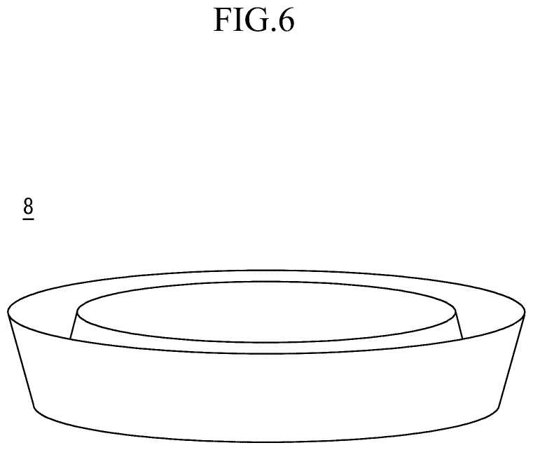

FIG. 6 is a view illustrating the inverse tapered portion according to the second embodiment of the present disclosure. An aspect of the inverse tapered portion 8 may be such that an inverse tapered shape is indicated, for example, by each of two slopes making a circuit in a ring shape.

Note that while an aspect has been indicated in the present embodiment in which the inverse tapered portion 8 is provided at a boundary between the opening portion 24 and the collection portion 26, the present disclosure is not limited to this. For example, the inverse tapered portion 8 may be provided at any height inside the opening portion 24 or may be provided at any height inside the collection portion 26.

As described above, according to the present embodiment, it is possible to prevent the film formed in the peripheral portion on the upper surface of the susceptor 2 from adhering to the upper surface of the substrate 4. Particularly, according to the present embodiment, it is more effectively inhibit the foreign material floating from the bottom surface of the foreign material collection region 25 during growth of the epitaxial layer from reaching the circumference of the substrate 4.

### Third Embodiment

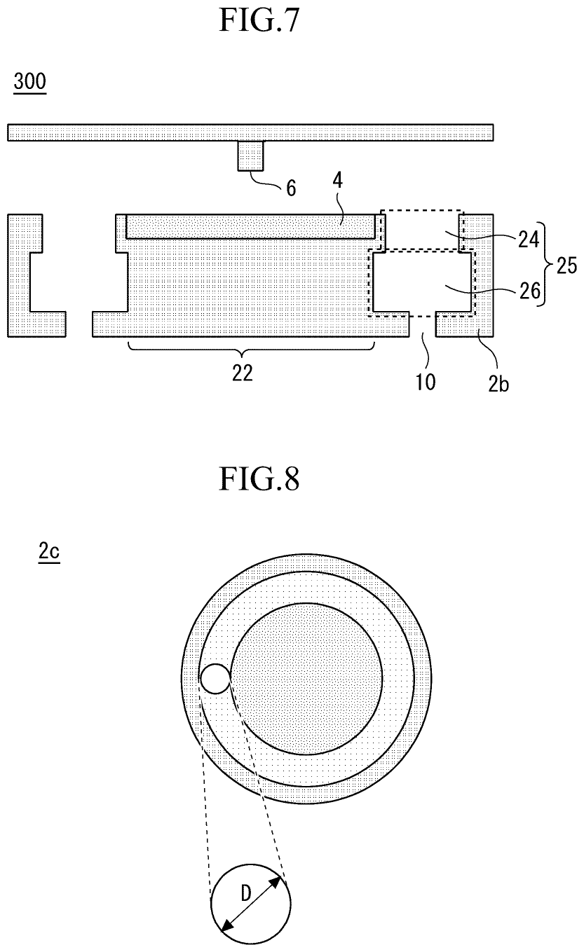

FIG. 7 is a view illustrating a semiconductor manufacturing apparatus according to a third embodiment of the present disclosure. A semiconductor manufacturing apparatus 300 is different from the semiconductor manufacturing apparatus 100 in that a susceptor 2b including an outlet 10 is provided.

The semiconductor manufacturing apparatus 300 includes the susceptor 2b. The susceptor 2b includes the outlet 10 on the bottom surface of the collection portion 26. The collection portion 26 locally has a negative pressure by the outlet 10. Thus, the foreign material that has deposited in the collection portion 26 is likely to be discharged from the outlet 10 in a case where the foreign material floats. This results in making it further difficult for the foreign material to reach the circumference of the substrate 4.

FIG. 8 is a top view illustrating a first modification of the susceptor according to the third embodiment of the present disclosure. A susceptor 2c may have an aspect in which one circular outlet 10 is provided.

Here, a diameter of the circular outlet 10 is set as D. The diameter D may be determined in accordance with a film thickness of the foreign material to be deposited by the semiconductor manufacturing apparatus 300 from start of film formation until internal reset. For example, the diameter D may be a value greater than the film thickness of the foreign material to be deposited by the semiconductor manufacturing apparatus 300 from start of film formation until internal reset.

A specific example will be described. For example, it is assumed that a total cumulative film thickness of the epitaxial layer made to grow by the semiconductor manufacturing apparatus 300 from start of film formation until internal reset is 200 μm. In this case, a film thickness of the foreign material locally deposited in an outer end portion of the holder portion 22 is approximately 100 μm. Thus, the diameter D is preferably set at 200 to 300 μm that is a value greater than the film thickness of the foreign material.

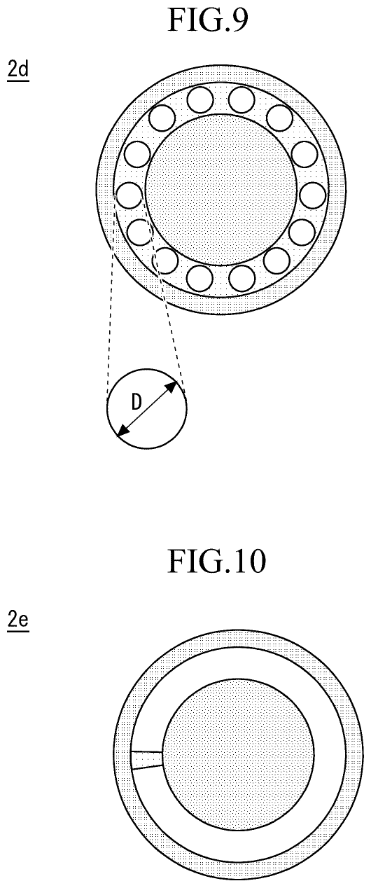

FIG. 9 is a top view illustrating a second modification of the susceptor according to the third embodiment of the present disclosure. A susceptor 2d may have an aspect in which a plurality of circular outlets 10 each having the diameter D are provided.

FIG. 10 is a top view illustrating a third modification of the susceptor according to the third embodiment of the present disclosure. A susceptor 2e may have an aspect in which a C-shaped outlet 10 is provided.

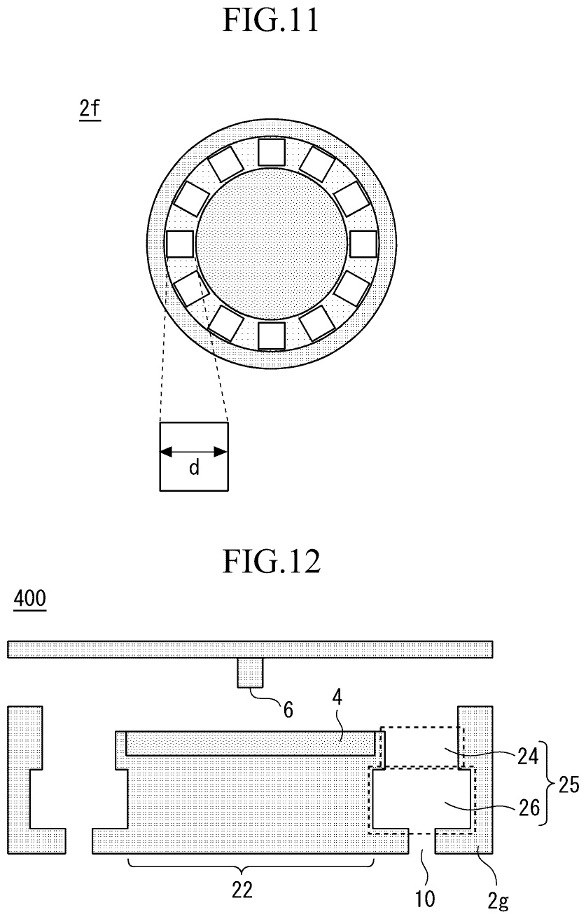

FIG. 11 is a top view illustrating a fourth modification of the susceptor according to the third embodiment of the present disclosure. A susceptor 2f may have an aspect in which a plurality of rectangular outlets 10 are provided.

Here, a length d of one side of the rectangular outlet 10 will be considered. The length d may be determined in accordance with the film thickness of the foreign material to be deposited by the semiconductor manufacturing apparatus 300 from start of film formation until internal reset. For example, the length d may be a value greater than the film thickness of the foreign material to be deposited by the semiconductor manufacturing apparatus 300 from start of film formation until internal reset.

A specific example will be described. For example, it is assumed that the total cumulative film thickness of the epitaxial layer made to grow by the semiconductor manufacturing apparatus 300 from start of film formation until internal reset is 200 μm. In this case, a film thickness of the foreign material locally depositing in an outer end portion of the holder portion 22 is approximately 100 μm. Thus, the length d is preferably set at 200 to 300 μm that is a value greater than the film thickness of the foreign material.

As described above, according to the present embodiment, it is possible to prevent the film formed in the peripheral portion on the upper surface of each susceptor from adhering to the upper surface of the substrate 4. Particularly, according to the present embodiment, it is possible to more effectively inhibit the foreign material floating during growth of the epitaxial layer from reaching the circumference of the substrate 4 by the effect of the outlet 10.

### Fourth Embodiment

FIG. 12 is a view illustrating a semiconductor manufacturing apparatus according to a fourth embodiment of the present disclosure. A semiconductor manufacturing apparatus 400 is different from the semiconductor manufacturing apparatus 300 in that the semiconductor manufacturing apparatus 400 includes a susceptor 2g having a high external wall.

The semiconductor manufacturing apparatus 400 includes the susceptor 2g. The susceptor 2g includes an external wall extending to a higher position than a surface on which the substrate 4 is to be placed in the holder portion 22. In other words, the foreign material collection region 25 is a region enclosed by the holder portion 22 and the external wall.

The foreign material collides with the external wall when the foreign material flows into the foreign material collection region 25 by inflow of the gas. This results in making it easier for the foreign material to flow into the foreign material collection region 25.

As described above, according to the present embodiment, it is possible to prevent the film formed in the peripheral portion on the upper surface of the susceptor 2g from adhering to the upper surface of the substrate 4. Particularly, according to the present embodiment, it is possible to more effectively inhibit the foreign material floating during growth of the epitaxial layer from reaching the circumference of the substrate 4.

Hereinafter, various aspects of the present disclosure will be collectively described as appendixes.

### (Appendix 1)

A semiconductor manufacturing apparatus, comprising:
a susceptor; and
a gas inlet located above the susceptor, wherein
the susceptor includes a holder portion on which a substrate is to be placed, and a foreign material collection region provided to enclose a peripheral region of the holder portion,
the foreign material collection region includes an opening portion, an opening of which is located at the same level as an uppermost portion of the holder portion, and a collection portion located at a lower level than the opening portion,
an opening width of the opening portion is narrower than an opening width of the collection portion, and
gas introduced from the gas inlet flows toward an outer periphery from a center of the substrate on an upper surface of the substrate and flows into the opening portion.

### (Appendix 2)

The semiconductor manufacturing apparatus according to appendix 1, wherein the offset portion is concave to an inward side of a line segment connecting an end point on the intersection point side of the first side and an end point on the intersection point side of the second side. (Appendix 3)

The semiconductor manufacturing apparatus according to appendix 1 or 2, wherein the susceptor includes an outlet on a bottom surface of the collection portion.

### (Appendix 4)

The semiconductor manufacturing apparatus according to appendix 3, wherein the outlet has a circular shape having a diameter of 200 to 300 μm.

### (Appendix 5)

The semiconductor manufacturing apparatus according to appendix 3, wherein the outlet has a C shape.

### (Appendix 6)

The semiconductor manufacturing apparatus according to appendix 3, wherein the outlet has a rectangular shape having one side of 200 to 300 μm.

### (Appendix 7)

The semiconductor manufacturing apparatus according to any one of appendixes 3 to 6, wherein a plurality of the outlets are provided.

### (Appendix 8)

The semiconductor manufacturing apparatus according to any one of appendixes 1 to 7, wherein the susceptor has an external wall extending to a higher position than a surface on which the substrate is to be placed in the holder portion.

### (Appendix 9)

The semiconductor manufacturing apparatus according to any one of appendixes 1 to 8, wherein the opening width of the opening portion is 200 to 300 μm.

### (Appendix 10)

The semiconductor manufacturing apparatus according to any one of appendixes 1 to 9, wherein
the susceptor further includes an upper ring cover and a lower ring cover that are ring-shaped covers provided on an outer periphery of the holder portion,
the opening portion is a region enclosed by the holder portion and the upper ring cover, and
the collection portion is a region enclosed by the holder portion and the lower ring cover.

### (Appendix 11)

The semiconductor manufacturing apparatus according to any one of appendixes 1 to 9, wherein
the susceptor further includes a ring cover provided on an outer periphery of the holder portion,
the foreign material collection region is a region enclosed by the holder portion and the ring cover, and
the ring cover is a ring-shaped cover having an inner diameter on an upper surface side smaller than an inner diameter on a bottom surface side.

### (Appendix 12)

A method for manufacturing a semiconductor apparatus that is a process of manufacturing the semiconductor apparatus to be implemented by a semiconductor manufacturing apparatus including a susceptor and a gas inlet located above the susceptor,
the susceptor including a holder portion on which a substrate is to be placed, and a foreign material collection region provided to enclose a peripheral region of the holder portion,
the foreign material collection region including an opening portion, an opening of which is located at the same level as an uppermost portion of the holder portion, and a collection portion located at a lower level than the opening portion,
an opening width of the opening portion being narrower than an opening width of the collection portion, and
the method comprising:
a step of placing the substrate on the holder portion;
a step of introducing gas from the gas inlet; and
a step of causing the gas flowing toward an outer periphery from a center of the substrate on an upper surface of the substrate to flow into the opening portion and collecting a foreign material in the foreign material collection region.

Obviously many modifications and variations of the present disclosure are possible in the light of the above teachings. It is therefore to be understood that within the scope of the appended claims the disclosure may be practiced otherwise than as specifically described.

The entire disclosure of a Japanese Patent Application No. 2024-088087, filed on May 30, 2024 including specification, claims, drawings and summary, on which the Convention priority of the present application is based, are incorporated herein by reference in its entirety.

1. A semiconductor manufacturing apparatus, comprising:
a susceptor; and
a gas inlet located above the susceptor, wherein
the susceptor includes a holder portion on which a substrate is to be placed, and a foreign material collection region provided to enclose a peripheral region of the holder portion, the foreign material collection region includes an opening portion, an opening of which is located at the same level as an uppermost portion of the holder portion, and a collection portion located at a lower level than the opening portion,
an opening width of the opening portion is narrower than an opening width of the collection portion, and
gas introduced from the gas inlet flows toward an outer periphery from a center of the substrate on an upper surface of the substrate and flows into the opening portion.

2. The semiconductor manufacturing apparatus according to claim 1, wherein the offset portion is concave to an inward side of a line segment connecting an end point on the intersection point side of the first side and an end point on the intersection point side of the second side.

3. The semiconductor manufacturing apparatus according to claim 1, wherein the susceptor includes an outlet on a bottom surface of the collection portion.

4. The semiconductor manufacturing apparatus according to claim 3, wherein the outlet has a circular shape having a diameter of 200 to 300 μm.

5. The semiconductor manufacturing apparatus according to claim 3, wherein the outlet has a C shape.

6. The semiconductor manufacturing apparatus according to claim 3, wherein the outlet has a rectangular shape having one side of 200 to 300 μm.

7. The semiconductor manufacturing apparatus according to claim 3, wherein a plurality of the outlets are provided.

8. The semiconductor manufacturing apparatus according to claim 1, wherein the susceptor has an external wall extending to a higher position than a surface on which the substrate is to be placed in the holder portion.

9. The semiconductor manufacturing apparatus according to claim 1, wherein the opening width of the opening portion is 200 to 300 μm.

10. The semiconductor manufacturing apparatus according to claim 1, wherein
the susceptor further includes an upper ring cover and a lower ring cover that are ring-shaped covers provided on an outer periphery of the holder portion,
the opening portion is a region enclosed by the holder portion and the upper ring cover, and
the collection portion is a region enclosed by the holder portion and the lower ring cover.

11. The semiconductor manufacturing apparatus according to claim 1, wherein
the susceptor further includes a ring cover provided on an outer periphery of the holder portion,
the foreign material collection region is a region enclosed by the holder portion and the ring cover, and
the ring cover is a ring-shaped cover having an inner diameter on an upper surface side smaller than an inner diameter on a bottom surface side.

12. A method for manufacturing a semiconductor apparatus that is a process of manufacturing the semiconductor apparatus to be implemented by a semiconductor manufacturing apparatus including a susceptor and a gas inlet located above the susceptor,
the susceptor including a holder portion on which a substrate is to be placed, and a foreign material collection region provided to enclose a peripheral region of the holder portion,
the foreign material collection region including an opening portion, an opening of which is located at the same level as an uppermost portion of the holder portion, and a collection portion located at a lower level than the opening portion,
an opening width of the opening portion being narrower than an opening width of the collection portion, and
the method comprising:
a step of placing the substrate on the holder portion;
a step of introducing gas from the gas inlet; and
a step of causing the gas flowing toward an outer periphery from a center of the substrate on an upper surface of the substrate to flow into the opening portion and collecting a foreign material in the foreign material collection region.

13. The semiconductor manufacturing apparatus according to claim 4, wherein a plurality of the outlets are provided.

14. The semiconductor manufacturing apparatus according to claim 5, wherein a plurality of the outlets are provided.

15. The semiconductor manufacturing apparatus according to claim 6, wherein a plurality of the outlets are provided.
